(19) United States
(12) Patent Application Publication
(10) Pub. No.: US 2024/0243154 A1
(43) Pub. Date: Jul. 18, 2024

(54) IMAGING SENSOR AND IMAGING DEVICE

(71) Applicant: SONY SEMICONDUCTOR SOLUTIONS CORPORATION, KANAGAWA (JP)

(72) Inventor: HIROSHI KATAYAMA, KANAGAWA (JP)

(21) Appl. No.: 18/559,366

(22) PCT Filed: Mar. 9, 2022
(86) PCT No.: PCT/JP2022/010267

§ 371 Date: Nov. 7, 2023

(30) Foreign Application Priority Data
May 25, 2021 (JP) 2021-087606

(51) Int. Cl. H01L 27/146; H01L 23/00; H01L 23/522; H04N 25/77; H04N 25/79

(52) U.S. Cl. CPC H01L 27/14634; H01L 23/5223; H01L 24/08; H01L 27/14636; H04N 25/77; H04N 25/79; H01L 2224/08145

(57) ABSTRACT

An object is to reduce a pixel size. A first semiconductor chip includes a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit. A second semiconductor chip is stacked on the first semiconductor chip, and the second semiconductor chip includes a comparison unit that compares the analog image signal with a reference signal whose voltage changes at a predetermined ratio as time elapses, and a conversion unit that converts the analog image signal into a digital image signal based on a result of the comparison. An image signal line transmits an analog image signal output from the pixel circuit to the comparison unit via a connection unit and a coupling capacitor disposed between the first semiconductor chip and the second semiconductor chip. At least one of the comparison unit and the conversion unit is disposed at a position overlapping the pixel circuit in plan view.

### FIELD

The present disclosure relates to an imaging sensor and an imaging device.

### BACKGROUND

An imaging sensor in which pixels including a photoelectric conversion device that performs photoelectric conversion of incident light are disposed in a two-dimensional matrix is used. Each pixel generates and outputs an image signal corresponding to a charge generated through photoelectric conversion. The image signal, which is an analog signal, is converted into a digital image signal by an analog-to-digital converter and output to the outside of the imaging sensor.

The analog-to-digital converter includes a comparison unit that compares an analog image signal with a reference signal whose voltage changes in a ramp shape, and outputs a digital image signal corresponding to the analog image signal based on a result of the comparison in the comparison unit. Specifically, the comparison unit outputs a signal as a result of the comparison when the analog image signal and the reference signal become equal. The period from the start of the comparison in the comparison unit to the output of the signal of the comparison result corresponds to the voltage of the analog image signal on a one-to-one basis. Thus, by generating and outputting a digital signal corresponding to this period, an analog image signal can be converted into a digital image signal.

An imaging sensor in which the analog-to-digital converter is disposed for each pixel has been proposed (see, for example, Patent Literature 1). The comparison unit of the conventional technology includes two transistors constituting a differential pair. A reference signal is applied to a gate terminal of one of the two transistors constituting the differential pair, and an analog image signal is input to a gate terminal of the other transistor. A constant current load is connected to each of these transistors. This configuration causes a current corresponding to a difference between the reference signal and the analog image signal to flows through each transistor, and the current is converted into a voltage by a constant current load and output.

In this conventional technology, pixels and the analog-to-digital converters are disposed separately in two semiconductor chips, an upper chip and a lower chip. Stacking of the upper chip and the lower chip is performed for downsizing the pixels and the analog-to-digital converters. The pixels and the two transistors constituting a differential pair of the comparison unit of the analog-to-digital converters are disposed on the upper chip, and the remaining portion of the analog-to-digital converters including two constant current loads of the differential pair is disposed on the lower chip. When the upper chip and the lower chip are stacked, the transistors of the differential pair and the constant current load are connected via a connection unit. For this connection unit, a connection unit formed by joining electrodes disposed on respective semiconductor chips is used.

### CITATION LIST

### Patent Literature

Patent Literature 1: JP 2018-113637 A

### SUMMARY

### Technical Problem

However, the above-described conventional technique has a problem that it is difficult to reduce the pixel size. Since the differential pair of the comparison unit and the constant current load are separated from each other, a connection unit is required for each of the two transistors of the differential pair. The connection unit has a relatively large area. This is for absorbing positional deviation at the time of stacking two semiconductor chips. Since two such connection units are disposed, there is a problem that the pixel size cannot be reduced.

The present disclosure proposes an imaging sensor and an imaging device that can be downsized.

### Solution to Problem

The present disclosure has been conceived to solve the problem described above, and the aspect thereof is an imaging sensor includes: a first semiconductor chip including a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit; a second semiconductor chip stacked on the first semiconductor chip, the second semiconductor chip including a comparison unit that compares the analog image signal with a reference signal whose voltage changes at a predetermined ratio as time elapses, and a conversion unit that converts the analog image signal into a digital image signal based on a result of the comparison; and an image signal line that transmits an analog image signal output from the pixel circuit to the comparison unit via a connection unit and a coupling capacitor disposed between the first semiconductor chip and the second semiconductor chip, wherein at least one of the comparison unit and the conversion unit is disposed at a position overlapping the pixel circuit in plan view.

### BRIEF DESCRIPTION OF DRAWINGS

FIG. 1 is a block diagram illustrating a configuration of an example of an imaging device applicable to each embodiment of the present disclosure.

FIG. 2 is a block diagram illustrating an example of a configuration pixels applicable to each embodiment.

FIG. 3 is a diagram illustrating an example of a structure of an imaging device 1000 applicable to each embodiment.

FIG. 4 is a diagram illustrating a configuration example of a pixel circuit and a comparison unit according to a first embodiment of the present disclosure.

FIG. 5 is a diagram illustrating a configuration example of a connection unit according to the first embodiment of the present disclosure.

FIG. 6 is a diagram illustrating an example of generation of image signals according to the first embodiment of the present disclosure.

FIG. 7A is a diagram illustrating another configuration example of the pixel circuit and the comparison unit according to the first embodiment of the present disclosure.

FIG. 7B is a diagram illustrating another configuration example of the pixel circuit and the comparison unit according to the first embodiment of the present disclosure.

FIG. 8 is a view illustrating another configuration example of the connection unit according to the first embodiment of the present disclosure.

FIG. 9 is a diagram illustrating a configuration example of a pixel circuit and a comparison unit according to a second embodiment of the present disclosure.

FIG. 10 is a diagram illustrating an example of generation of image signals according to the second embodiment of the present disclosure.

### DESCRIPTION OF EMBODIMENTS

Hereinafter, embodiments of the present disclosure will be described in detail with reference to the drawings. The description will be given in the following order. In each of the following embodiments, the same portions are denoted by the same reference signs, and repetitive description will be omitted.
1. First Embodiment
2. Second Embodiment

### 1. First Embodiment

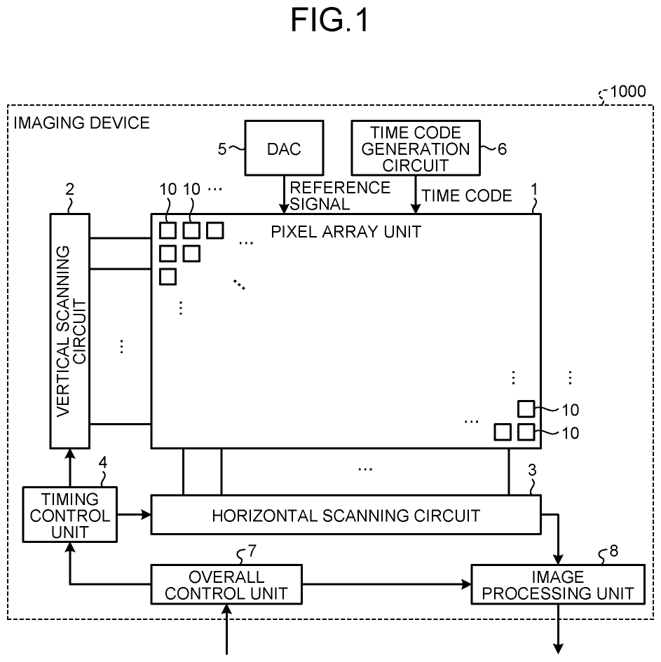

FIG. 1 is a block diagram illustrating a configuration of an example of an imaging device applicable to each embodiment of the present disclosure. In FIG. 1, an imaging device 1000 includes a pixel array unit 1, a vertical scanning circuit 2, a horizontal scanning circuit 3, a timing control unit 4, a digital to analog converter (DAC) 5, a time code generation circuit 6, an overall control unit 7, and an image processing unit 8.

The pixel array unit 1 includes a plurality of pixels 10. Each pixel 10 includes a photodetector, a pixel circuit, a conversion circuit, and a storage unit. Although details will be described later, the photodetector generates a charge corresponding to light received through photoelectric conversion. The pixel circuit reads the charge generated in the photodetector and outputs the charge as an analog signal. The conversion circuit converts the analog signal output from the pixel circuit into a pixel signal that is a digital signal based on a reference signal. The storage unit stores the pixel signal converted by the conversion circuit. The pixel 10 may further include a signal processing circuit that performs correlated double sampling (CDS) processing for reducing noise on the pixel signal.

In the pixel array unit 1, the plurality of pixels 10 are disposed in a matrix array in a horizontal direction (row direction) and a vertical direction (column direction). In the pixel array unit 1, the arrangement of the pixels 10 in the row direction is referred to as a line. A one-frame image (image data) is formed by pixel signals read from a predetermined number of lines in the pixel array unit 1. For example, in a case where a one-frame image is formed of 3000 pixels×2000 lines, the pixel array unit 1 includes at least 2000 lines each including at least 3000 of pixels 10.

Under the control of the overall control unit 7 described later, the vertical scanning circuit 2 generates a control signal such as a drive pulse when a pixel signal is read from each pixel 10, and supplies the control signal for each row of the pixel array unit 1. The horizontal scanning circuit 3 performs a selection operation of selecting each column of the pixel array unit 1 in a predetermined order under the control of the overall control unit 7. Each pixel signal held in the storage unit in the corresponding pixel 10 is sequentially output. The horizontal scanning circuit 3 is configured using, for example, a shift register, an address decoder, and the like.

The timing control unit 4 generates one or more types of clock signals for controlling the operation of each unit of the imaging device 1000, for example, under the control of the overall control unit 7. The clock signal generated by the timing control unit 4 is supplied to the vertical scanning circuit 2 and the horizontal scanning circuit 3. Although not illustrated, the clock signal generated by the timing control unit 4 is also supplied to the DAC 5 and the time code generation circuit 6.

The DAC 5 generates a reference signal used in the conversion circuit in each pixel 10. For example, the DAC 5 generates a reference signal (RAMP signal) in which the voltage decreases (or increases) stepwise according to a constant inclination based on the clock signal supplied from the timing control unit 4 and a digital value whose value drops (or rises) according to the clock signal supplied from the overall control unit 7. The reference signal generated by the DAC 5 is supplied to the pixel array unit 1 and passed to each pixel 10 included in the pixel array unit 1.

In the following description, unless otherwise specified, start of inclination (voltage drop or rise) of the reference signal is described as start of the reference signal. The end of the inclination of the reference signal is described as end of the reference signal.

The time code generation circuit 6 generates a time code according to the inclination of the voltage in the reference signal. For example, the clock signal is supplied from the timing control unit 4 to the time code generation circuit 6, and the signal indicating start of the reference signal is supplied from the overall control unit 7 to the time code generation circuit 6. When the reference signal is started, the time code generation circuit 6 performs counting according to the clock signal and generates a time code indicating a time for each count. The time code generated by the time code generation circuit 6 is supplied to the pixel array unit 1 and passed to each pixel 10.

The overall control unit 7 includes, for example, a processor, and controls the overall operation of the imaging device 1000 according to a predetermined program. The overall control unit 7 may also control the overall operation of the imaging device 1000 according to a control signal input from the outside.

The image processing unit 8 includes, for example, a frame memory, and stores the pixel signal for one frame output from the horizontal scanning circuit 3. The image processing unit 8 performs predetermined image processing on the stored pixel signals for one frame. The image processing here may be processing such as gain adjustment and white balance adjustment. The image processing unit 8 is not limited to the processing, and the image processing unit 8 can also execute processing such as edge extraction and face determination.

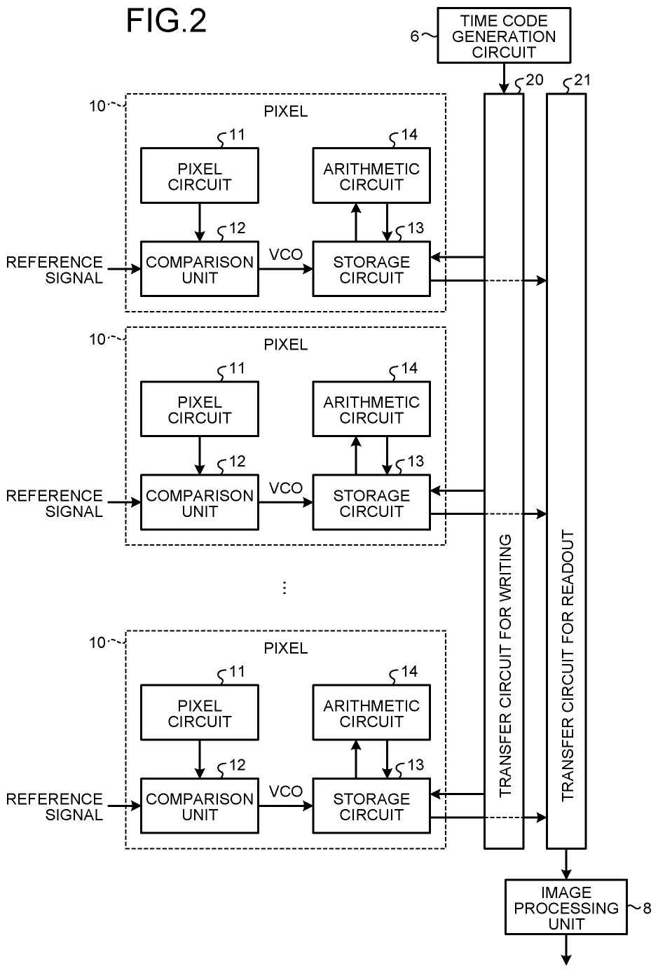

FIG. 2 is a block diagram illustrating an example of a configuration pixels applicable to each embodiment. In FIG. 2, each pixel 10 includes a pixel circuit 11, a comparison unit 12, a storage circuit 13, and an arithmetic circuit 14. The comparison unit 12, the storage circuit, and the arithmetic circuit 14 constitute an analog digital converter (ADC).

The pixel circuit 11 includes a photodetector and a readout circuit. The readout circuit reads out a charge generated according to light received by the photodetector from the photodetector. The readout circuit outputs an analog signal of a voltage corresponding to the read out charge. The analog signal output from the readout circuit is supplied to the comparison unit 12. Further, a reference signal is supplied from the DAC 5 to the comparison unit 12.

Although details will be described later, the DAC 5 generates a reference signal for detecting a reset level of the readout circuit in one readout processing from the readout circuit, and then generates a reference signal for detecting a level of the analog signal read from the readout circuit.

The comparison unit 12 compares the analog signal supplied from the pixel circuit 11 with the reference signal supplied from the DAC 5 and inverts an output signal VCO when the voltage level relationship between the analog signal and the reference signal is inverted. The output signal VCO of the comparison unit 12 is supplied to the storage circuit 13.

The time code generation circuit 6 generates a time code updated for each clock according to, for example, a clock signal. The time code generated by the time code generation circuit 6 is supplied to a transfer circuit for writing 20. The transfer circuit for writing 20 is provided, for example, for each column in the pixel array unit 1, and the plurality of pixels 10 aligned in the corresponding column are connected to the circuit. The transfer circuit for writing 20 supplies the time code supplied from the time code generation circuit 6 to each connected pixel 10.

The storage circuit 13 is, for example, a latch circuit, and holds the time code supplied from the transfer circuit for writing 20. For example, the storage circuit 13 updates the time code supplied and held immediately before with the time code supplied from the transfer circuit for writing 20. The storage circuit 13 stops updating the time code at the timing when the output signal VCO supplied from the comparison unit 12 is inverted.

The arithmetic circuit 14 performs noise removal processing on the analog signal read out from the readout circuit based on the time code held in the storage circuit 13. For example, the arithmetic circuit 14 performs an arithmetic operation to obtain a difference between the time code held on the basis of the reference signal for detecting the reset level of the readout circuit and the time code held on the basis of the reference signal for detecting the level of the analog signal read out from the readout circuit. Based on this difference, pixel data can be obtained. This pixel data is pixel data from which offset noise has been removed, and is returned to the storage circuit 13. The storage circuit 13 holds the pixel data returned from the arithmetic circuit 14.

At the timing of the end of the reference signal, for example, for each row, pixel data from which noise has been removed is read out from the storage circuit 13 of each pixel 10 aligned in the row, and the read out pixel data is output via the transfer circuit for readout 21.

The transfer circuit for readout 21 reads out a time code from the pixel 10 designated by each of the vertical scanning circuit 2 and the horizontal scanning circuit 3, for example, and outputs the time code as pixel data. The pixel data output from the transfer circuit for readout 21 is supplied to the image processing unit 8 and stored in the frame memory. For example, when pixel data for one frame is stored in the frame memory, the image processing unit 8 performs predetermined image processing on the pixel data stored in the frame memory, and outputs the pixel data to the outside of the imaging device 1000, for example. The image processing unit 8 is an example of a processing circuit described in the claims.

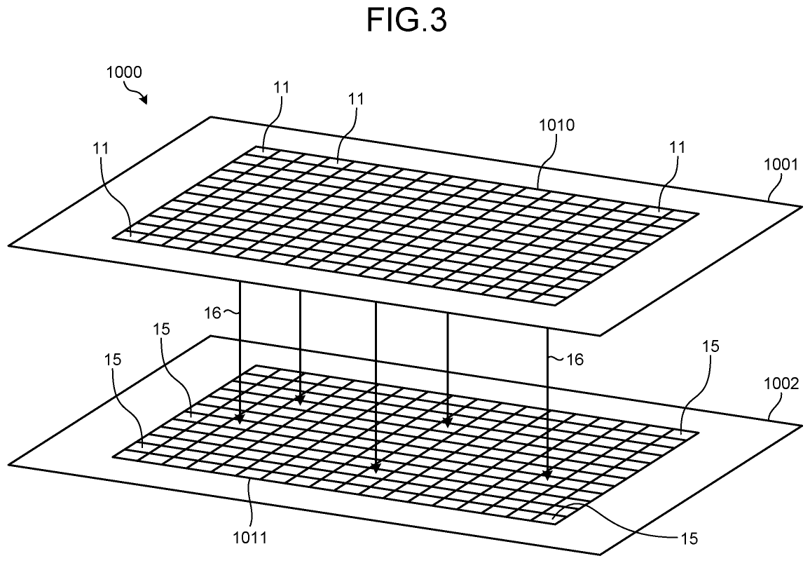

FIG. 3 is a diagram illustrating an example of a structure of the imaging device 1000 applicable to each embodiment. In FIG. 3, the imaging device 1000 is formed as one imaging device 1000 by bonding a first semiconductor chip 1001 and a second semiconductor chip 1002 while electrically contacting them via a conductive path 16, for example.

In the first semiconductor chip 1001, a pixel region 1010 is disposed. In the pixel region 1010, photodetectors are disposed in a matrix. In the example of FIG. 3, the pixel circuits 11 are disposed in a matrix with respect to the pixel region 1010. In the second semiconductor chip 1002, a pixel logic region 1011 is disposed. In the pixel logic region 1011, for example, processing circuits 15 corresponding to the pixel circuits 11 are disposed in a matrix corresponding to the disposition of the pixel circuits 11 in the first semiconductor chip 1001. Each processing circuit 15 includes, for example, the comparison unit 12, the storage circuit 13, and the arithmetic circuit 14 illustrated in FIG. 3. That is, the pixel 10 includes the pixel circuit 11 disposed on the first semiconductor chip 1001 and the processing circuit 15 disposed on the second semiconductor chip 1002 on a one-to-one basis with respect to the pixel circuit 11.

As will be described later, the pixel circuit 11 is connected to the comparison unit 12 of the processing circuit 15. The pixel circuit 11 and the comparison unit 12 are connected by an image signal line 18. A plurality of pixel circuits 11 are disposed in the first semiconductor chip 1001, and a plurality of processing circuits 15 are included in the second semiconductor chip 1002. The plurality of pixel circuits 11 and the plurality of processing circuits 15 are connected by a plurality of image signal lines 18, respectively. These image signal lines 18 constitute the above-described conductive path 16. The conductive path 16 includes a ground line that transmits a reference potential, a power supply line that supplies power, and the like.

### [Configuration of Pixel Circuit and Comparison Unit]

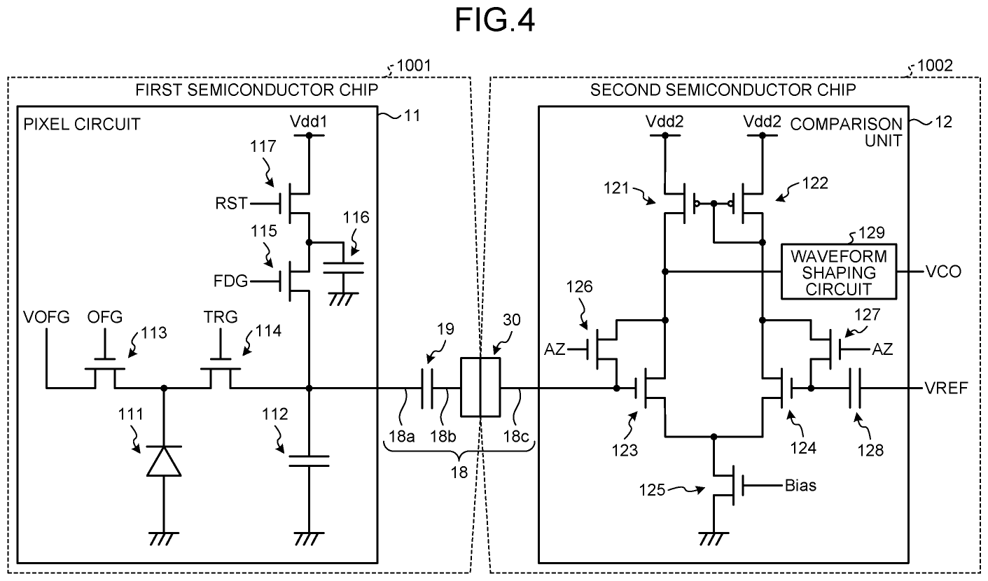

FIG. 4 is a diagram illustrating a configuration example of a pixel circuit and a comparison unit according to the first embodiment of the present disclosure. The drawing is a circuit diagram illustrating a configuration example of the pixel circuit 11 and the comparison unit 12. As described above, the pixel circuit 11 is disposed on the first semiconductor chip 1001, and the comparison unit 12 is disposed on the second semiconductor chip 1002. The first semiconductor chip 1001 and the second semiconductor chip 1002 are bonded and stacked.

The pixel circuit 11 and the comparison unit 12 are connected by the image signal line 18. The image signal line 18 connects an output of the pixel circuit 11 and an input of the comparison unit 12 via a coupling capacitor 19 and a connection unit 30. The connection unit 30 connects wirings disposed on different semiconductor chips. The connection unit 30 may be configured by joining pads (electrodes) disposed on the first semiconductor chip 1001 and the second semiconductor chip 1002 to each other. Details of the configuration of the connection unit 30 will be described later. The image signal line 18 between an output of the pixel circuit 11 and the coupling capacitor 19 will be referred to as an image signal line 18a. The image signal line 18 between the coupling capacitor 19 and the connection unit 30 will be referred to as an image signal line 18b. The image signal line 18 between the connection unit 30 and an input of the comparison unit 12 will be referred to as an image signal line 18c.

First, the pixel circuit 11 will be described. The pixel circuit 11 in the drawing includes a photoelectric conversion unit 111, a charge holding unit 112, a charge discharge unit 113, a charge transfer unit 114, a reset unit 117, a capacitance switching unit 115, and a second charge holding unit 116. The charge discharge unit 113, the charge transfer unit 114, the reset unit 117, and the capacitance switching unit 115 may be composed of n-channel MOS transistors. In these n-channel MOS transistors, a drain and a source may be conducted by applying a voltage exceeding a threshold value of a gate-source voltage Vgs to the gates. Hereinafter, the voltage exceeding the threshold value of the gate-source voltage Vgs is referred to as an ON voltage. A control signal including the ON voltage is referred to as an ON signal.

In the pixel circuit 11, a signal line VOFG, a signal line OFG, a signal line TRG, a signal line FDG, and a signal line RST are wired. The signal line VOFG is a signal line through which a charge held in the photoelectric conversion unit 111 described later is discharged. A positive voltage for discharging charges is applied to the signal line VOFG. The signal line OFG, the signal line TRG, the signal line FDG, and the signal line RST are signal lines for transmitting control signals to the gates of the charge discharge unit 113, the charge transfer unit 114, the capacitance switching unit 115, and the reset unit 117, respectively. These signal lines are signal lines for transmitting control signals from the vertical scanning circuit 2 described in FIG. 1. A power supply line Vdd1 for supplying power is further wired to the pixel circuit 11.

The anode of the photoelectric conversion unit 111 is grounded, and the cathode is connected to a source of the charge discharge unit 113 and a source of the charge transfer unit 114. The drain of the charge discharge unit 113 is connected to the signal line VOFG. The drain of the charge transfer unit 114 is connected to the source of the capacitance switching unit 115, one end of the charge holding unit 112, and the image signal line 18a. The other end of the charge holding unit 112 is grounded. The drain of the capacitance switching unit 115 is connected to the source of the reset unit 117 and one end of the second charge holding unit 116. The other end of the second charge holding unit 116 is grounded. The drain of the reset unit 117 is connected to the power supply line Vdd1. The gate of the charge discharge unit 113, the gate of the charge transfer unit 114, the gate of the capacitance switching unit 115, and the gate of the reset unit 117 are connected to the signal line OFG, the signal line TRG, the signal line FDG, and the signal line RST, respectively.

The photoelectric conversion unit 111 performs photoelectric conversion of incident light. The photoelectric conversion unit 111 may be composed of a photodiode. The photoelectric conversion unit 111 holds the charges generated through photoelectric conversion in the exposure period.

The charge discharge unit 113 discharges the charges held in the photoelectric conversion unit 111. The charge discharge unit 113 discharge the charges held in the photoelectric conversion unit 111 to the signal line VOFG by electrically connecting the signal line VOFG and the photoelectric conversion unit 111.

The charge holding unit 112 holds the charges generated by the photoelectric conversion unit 111. The charge holding unit 112 may be formed of a floating diffusion (FD) region which is a semiconductor region having a relatively high impurity concentration formed in a semiconductor substrate.

The charge transfer unit 114 transfers the charges generated by the photoelectric conversion unit 111 to the charge holding unit 112. The charge transfer unit 114 transfers the charges by electrically connecting the photoelectric conversion unit 111 and the charge holding unit 112.

The second charge holding unit 116 is connected in parallel to the charge holding unit 112 and holds the charges generated by the photoelectric conversion unit 111. The second charge holding unit 116 may be composed of a capacitor, for example.

The capacitance switching unit 115 connects the charge holding unit 112 and the second charge holding unit 116. When the capacitance switching unit 115 is in a non-conductive state, the charges generated by the photoelectric conversion unit 111 is held only in the charge holding unit 112. When the capacitance switching unit 115 is in a conductive state, the second charge holding unit 116 is connected in parallel to the charge holding unit 112, and the holding capacitance of the charges generated by the photoelectric conversion unit 111 increases. The capacitance switching unit 115 thus switches the capacitance of the charge holding unit. This configuration can change the conversion efficiency of the pixel circuit 11. When the capacitance switching unit 115 is in a non-conductive state, the conversion efficiency becomes high, and when the capacitance switching unit 115 is in a conductive state, the holding capacitance increases, and thus, the conversion efficiency becomes low. For example, when imaging is performed in a low illuminance environment, the capacitance switching unit 115 is made non-conductive to be in a mode with high conversion efficiency. When a high-luminance subject is imaged, the capacitance switching unit 115 is conducted to switch to a mode with low conversion efficiency. This configuration can prevent saturation of the charge holding unit 112.

The reset unit 117 resets the charge holding unit 112 and the second charge holding unit 116. The reset unit 117 performs reset by connecting the charge holding unit 112 and the power supply line Vdd1 via the capacitance switching unit 115 and discharging the charges of the charge holding unit 112 to the power supply line Vdd1. At this time, the second charge holding unit 116 is also reset.

The operation of the pixel circuit 11 is as follows. First, the charge discharge unit 113 is conducted to discharge the charges of the photoelectric conversion unit 111. As a result, the exposure period is started. During this exposure period, charges generated through photoelectric conversion is held in the photoelectric conversion unit 111. After a predetermined exposure period elapses, the reset unit 117 and the capacitance switching unit 115 are conducted to reset the charge holding unit 112 and the second charge holding unit 116. After completion of the reset, the charge transfer unit 114 is made conductive, and the charges held in the photoelectric conversion unit 111 are transferred to the charge holding unit 112. At this time, when the capacitance switching unit 115 is made conductive, some of the charges held in the photoelectric conversion unit 111 are transferred to the second charge holding unit 116. Since the image signal line 18 is connected to the charge holding unit 112, an image signal that is a signal of a voltage corresponding to the charges held in the charge holding unit 112 is output to the image signal line 18. The image signal is an analog signal. The analog image signal is compared with a reference signal by the comparison unit 12 described below.

The comparison unit 12 includes MOS transistors 121 to 127, a capacitor 128, and a waveform shaping circuit 129. The MOS transistors 121 and 122 may be composed of p-channel MOS transistors. The MOS transistors 123 to 127 may be composed of n-channel MOS transistors. A signal line AZ, A signal line VREF, and A signal line Bias are wired to the comparison unit 12. The signal line AZ is a signal line that transmits a control signal to the MOS transistors 126 and 127. The signal line VREF is a signal line that transmits the above-described reference signal. The signal line Bias is a signal line that supplies a bias voltage to the MOS transistor 125. A power supply line Vdd2 for supplying power is further wired to the comparison unit 12.

The image signal line 18c which is an input signal line of the comparison unit 12 is connected to the gate of the MOS transistor 123 and the source of the MOS transistor 126. The source of the MOS transistor 123 is connected to the drain of the MOS transistor 125 and the source of the MOS transistor 124. The source of the MOS transistor 125 is grounded. The drain of the MOS transistor 123 is connected to the drain of the MOS transistor 126, the drain of the MOS transistor 121, and the input of the waveform shaping circuit 129. The source of the MOS transistor 121 is connected to the power supply line Vdd2, and the gate of the MOS transistor 121 is connected to the gate of the MOS transistor 122, the drain of the MOS transistor 122, the drain of the MOS transistor 124, and the drain of the MOS transistor 127. The source of the MOS transistor 122 is connected to the power supply line Vdd2. The gate of the MOS transistor 124 is connected to the source of the MOS transistor 127 and one end of the capacitor 128. The other end of the capacitor 128 is connected to the signal line VREF. The gates of the MOS transistors 126 and 127 are commonly connected to the signal line AZ. The gate of the MOS transistor 125 is connected to the signal line Bias.

The MOS transistors 123 and 124 are transistors constituting a differential pair, and they output a difference between voltages applied to the respective gates. An analog image signal is applied to the gate of the MOS transistor 123 via the image signal line 18 (image signal line 18c), and the reference signal is applied to the gate of the MOS transistor 124 via the capacitor 128. Thus, the differential pair composed of the MOS transistors 123 and 124 detect a difference between the analog image signal and the reference signal. Specifically, a current corresponding to the difference between the analog image signal and the reference signal flows through the MOS transistors 123 and 124. This current is converted into a change in voltage by the MOS transistors 121 and 122 described later and is output as a comparison result. In the circuit of the drawing, the signal of the comparison result is output from the drain of the MOS transistor 123. This signal is input to the waveform shaping circuit 129.

The MOS transistors 121 and 122 are transistors configured in a constant current circuit and constituting loads of the MOS transistors 123 and 124, respectively. The MOS transistors 121 and 122 constitute a current mirror circuit and supply a source current to the MOS transistors 123 and 124. The MOS transistors 121 and 122 convert a change in current flowing through the MOS transistors 123 and 124 into a change in voltage. The MOS transistor 125 constitutes a constant current circuit and supplies a constant current to the differential pair composed of the MOS transistors 123 and 124. The MOS transistor 125 supplies a sink current corresponding to the bias voltage supplied by the signal line Bias to the MOS transistors 123 and 124.

The MOS transistors 126 and 127 initialize the differential pair composed of the MOS transistors 123 and 124. The initialization may be performed by causing the MOS transistor 126 to conduct between the drain and the gate of the MOS transistor 123 and causing the MOS transistor 127 to conduct between the drain and the gate of the MOS transistor 124. By this initialization, the voltages of the respective drains are applied as initial voltages to the gates of the MOS transistors 123 and 124. The coupling capacitor 19 is connected to the gate of the MOS transistor 123, and the capacitor 128 is connected to the gate of the MOS transistor 124. By the initialization, the coupling capacitor 19 and the capacitor 128 are charged to an initial voltage. This initialization is performed based on a control signal transmitted by the signal line AZ.

The capacitor 128 is a coupling capacitor that transmits a signal to the gate of the MOS transistor 124. The capacitor 128 is a capacitor that transmits an AC component of a signal like the coupling capacitor 19.

The waveform shaping circuit 129 shapes the waveform of the output signal of the differential pair composed of the MOS transistors 123 and 124. The waveform shaping circuit 129 includes an amplifier and a delay circuit, and it shapes a waveform by converting an output signal of the differential pair composed of the MOS transistors 123 and 124 into a signal having a predetermined pulse width.

Next, the operation of the comparison unit 12 will be described. As described above, the analog image signal is applied to the gate of the MOS transistor 123, and the reference signal is applied to the gate of the MOS transistor 124. A signal in which the voltage drop in a ramp shape is assumed as the reference signal. After initialization by the MOS transistors 126 and 127, the analog image signal and the reference signal are compared, and a current corresponding to the difference flows through the MOS transistors 123 and 124. At an initial stage, since the reference signal has a higher voltage than the analog image signal, a large amount of current flows through the MOS transistor 124 as compared with the MOS transistor 123. Since the gain of the differential pair in the drawing is high, the MOS transistor 124 enters a conductive state, and the MOS transistor 123 enters a substantially non-conductive state. Thus, the drain of the MOS transistor 123 has a high potential, and an H level signal is output.

Thereafter, when the voltage of the reference signal decreases to be less than the voltage of the analog image signal, the MOS transistor 124 transitions to a non-conductive state, and the MOS transistor 123 transitions to a conductive state. The drain of the MOS transistor 123 has a low potential, and an L level signal is output. The differential pair composed of the MOS transistors 123 and 124 in the drawing can thus detect the difference between the analog image signal and the reference signal. Further, by detecting the transition of the MOS transistor 123 from the non-conductive state to the conductive state, the timing at which the reference signal becomes equal to the analog image signal can be detected.

In this manner, a signal as a result of comparison between the analog image signal and the reference signal is output to the node to which the drain of the MOS transistor 123 is connected. This signal is transmitted to the storage circuit 13 described in FIG. 2 via the waveform shaping circuit 129 and is converted into a digital image signal. The storage circuit 13 is an example of a conversion unit described in the claims.

By simultaneously performing initialization by the MOS transistors 126 and 127 and resetting by the reset unit 117 of the pixel circuit 11, the coupling capacitor 19 can be charged to a potential difference corresponding to the initial overvoltage of the MOS transistor 123 and the voltage at the time of resetting the charge holding unit 112. As a result, the coupling capacitor 19 can transmit only the change in potential of the charge holding unit 112 to the comparison unit 12.

The power supply line Vdd1 is wired to the pixel circuit 11, and the power supply line Vdd2 is wired to the comparison unit 12. Since different power are supplied to the respective circuits in this manner, the influence of the fluctuation in the power supply voltage can be reduced.

### [Configuration of Connection Unit]

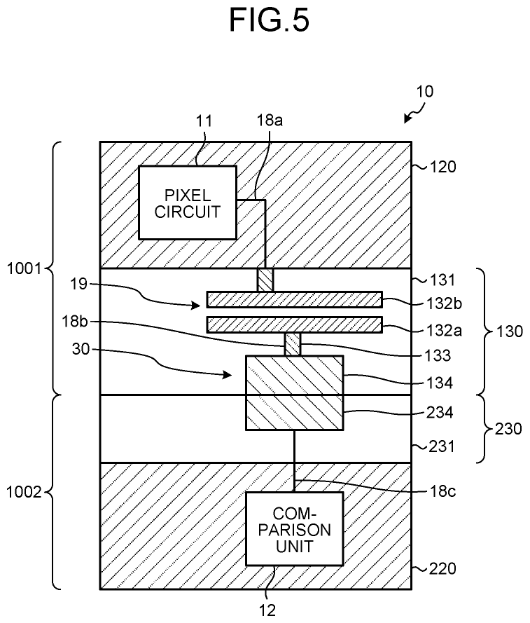

FIG. 5 is a diagram illustrating a configuration example of a connection unit according to the first embodiment of the present disclosure. The drawing is a sectional view illustrating a configuration example of the connection unit 30. The drawing is a sectional view illustrating a region of the connection unit 30 in the stacked first semiconductor chip 1001 and second semiconductor chip 1002.

The first semiconductor chip 1001 includes a semiconductor substrate 120 and a wiring region 130. The semiconductor substrate 120 is a semiconductor substrate on which devices such as the pixel circuit 11 are formed. The semiconductor substrate 120 may be made of silicon, for example.

The wiring region 130 is a region where wiring for transmitting a signal to the devices is formed. The wiring region 130 includes a wiring 132 and an insulating layer 131. The wiring 132 is a conductor that transmits a signal or the like to the devices. The wiring 132 may be made of copper (Cu), for example. The insulating layer 131 insulates the wiring 132. The insulating layer 131 may be made of silicon oxide (SiO₂), for example. A via plug 133 and a first pad 134 are further disposed in the wiring region 130 in the drawing. The via plug 133 is connected to the wiring 132 and the semiconductor substrate 120 disposed in different layers of the wiring region 130. The via plug 133 may be made of a columnar metal, for example.

Wirings 132a and 132b disposed in parallel are illustrated in the wiring region 130 of the drawing. The wirings 132a and 132b constitute the coupling capacitor 19. In this case, the insulating layer 131 between the wirings 132a and 132b constitutes a dielectric of the coupling capacitor 19.

The first pad 134 is an electrode that is joined to a second pad 234 to be described later to form the connection unit 30. The first pad 134 may be made of Cu, for example. The first pad 134 is embedded in the surface of the wiring region 130.

The pixel circuit 11 and the wiring 132a constituting the coupling capacitor 19 are connected by the image signal line 18a. In the drawing, the via plug 133 constitutes a part of the wiring 132a. The wiring 132a constituting the coupling capacitor 19 and the first pad 134 are connected by the via plug 133 constituting the image signal line 18b.

The second semiconductor chip 1002 includes a semiconductor substrate 220 and a wiring region 230. The semiconductor substrate 220 is a semiconductor substrate on which devices are formed as in the semiconductor substrate 120. On the semiconductor substrate 220, devices such as the comparison unit 12 and the storage circuit 13 (not illustrated) are disposed.

The wiring region 230 is a region where wiring for transmitting a signal to devices is formed like the wiring region 130. The second pad 234 is disposed in the wiring region 230. Description of wiring and the like is omitted in the wiring region 230 in the drawing.

Similarly to the first pad 134, the second pad 234 is an electrode made of Cu or the like, and is embedded in the surface of the wiring region 230. The second pad 234 and the comparison unit 12 are connected by the image signal line 18c.

The wiring region 130 of the first semiconductor chip 1001 and the wiring region 230 of the second semiconductor chip 1002 are joined, and the first semiconductor chip 1001 and the second semiconductor chip 1002 are stacked. At this time, the first pad 134 and the second pad 234 are aligned and joined to form the connection unit 30. This joining may be performed, for example, by heat-pressing the first pad 134 and the second pad 234.

The pixel circuit 11 is disposed at a position overlapping at least one of the comparison unit 12 and the storage circuit 13 in plan view. This configuration can reduce the size of the pixel 10 in plan view.

The coupling capacitor 19 is not limited to this example. For example, a metal insulator semiconductor (MIS) using a semiconductor region formed on the wiring 132 and the semiconductor substrate 120 as an electrode may be used.

As illustrated in the drawing, the coupling capacitor 19 is disposed in the first semiconductor chip 1001 to separate the output of the pixel circuit 11 and the connection unit 30, and thus, the influence of the parasitic capacitance of the connection unit 30 can be reduced. Specifically, since the parasitic capacitance of the connection unit 30 is not added to the charge holding unit 112 of the pixel circuit 11 connected to the image signal line 18, an increase in the capacitance of the charge holding unit 112 can be reduced, and a decrease in conversion efficiency can be prevented.

### [Generation of Image Signal]

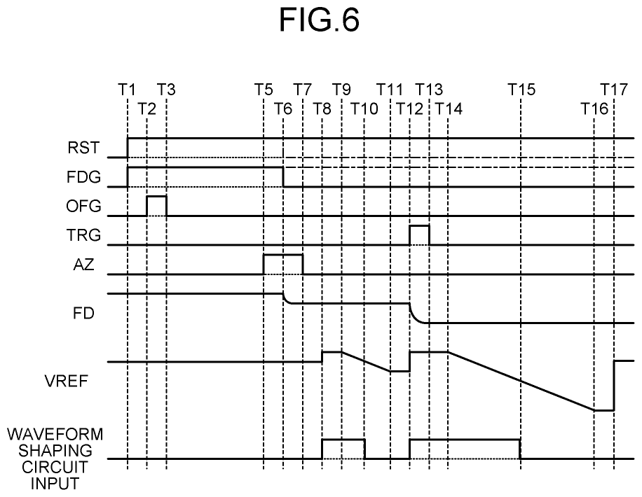

FIG. 6 is a diagram illustrating an example of generation of image signals according to the first embodiment of the present disclosure. The drawing is a timing chart illustrating processing in the pixel circuit 11 and the comparison unit 12. In the drawing, “RST”, “FDG”, “OFG”, “TRG”, and “AZ” represent control signals transmitted by the signal line RST, the signal line FDG, the signal line OFG, the signal line TRG, and the signal line AZ, respectively. A portion of the value “1” of these binarized control signals represents a signal of the above-described ON voltage. The broken lines in the drawing represent the level of 0 V. The control signal in the drawing represents an example of a control signal for applying a voltage of 0 V when the MOS transistor to be controlled is turned off. A different voltage, for example, −1 V may also be applied to the signal voltage for turning off the MOS transistor.

“FD” in the drawing represents an analog image signal to be input to the comparison unit 12. “VREF” represents the reference signal. “WAVEFORM SHAPING CIRCUIT INPUT” represents a signal input to the waveform shaping circuit 129.

In the initial state, the control signals of the signal line RST, the signal line FDG, the signal line OFG, the signal line TRG, and the signal line AZ have the value “0”. The analog image signal has a voltage at the time of resetting. The reference signal has a predetermined initial voltage.

At T1, an ON signal is applied from the signal line RST and the signal line FDG, and the reset unit 117 and the capacitance switching unit 115 are conducted. This causes the charge holding unit 112 and the second charge holding unit 116 to be reset. The input of the ON signal to the signal line FDG continues until T6.

At T2, an ON signal is applied from the signal line OFG, and the charge discharge unit 113 becomes conductive. This causes the charges of the photoelectric conversion unit 111 to be discharged.

At T3, the application of the ON signal from the signal line OFG stops. As a result, the exposure period is started. Charges generated through photoelectric conversion are held and accumulated in the photoelectric conversion unit 111.

At T5, an ON signal is applied from the signal line AZ, and the MOS transistors 126 and 127 are conducted. This causes the comparison unit 12 to be initialized.

At T6, the application of the ON signal to the signal line FDG stops. As a result, the analog image signal has a voltage based on the charges or the like remaining in the charge holding unit 112.

At T7, the application of the ON signal to the signal line AZ stops.

At T8, a reference signal is applied from the signal line VREF. At this time, an initial value of the reference signal is applied. Since this initial value is a higher voltage than the voltage of the analog image signal, the MOS transistor 124 constituting the differential pair becomes conductive, and the MOS transistor 123 becomes non-conductive. Thus, the waveform shaping circuit input becomes an H level signal.

At T9, the ramp-shaped voltage drop of the reference signal starts.

At T10, the reference signal becomes equal to the analog image signal. As a result, the waveform shaping circuit input transitions to an L level. This signal is shaped by the waveform shaping circuit 129 and input to the storage circuit 13 described in FIG. 2. The storage circuit 13 captures and stores the time code transferred by the transfer circuit for writing 20 at this time. This captured time code corresponds to the elapsed time from the start of the decrease of the reference signal at T9. The elapsed time corresponding to the voltage of the analog image signal at the time of reset can be thus acquired.

At T11, the ramp-shaped voltage drop of the reference signal stops.

At T12, an ON signal is applied from the signal line TRG, and the charge transfer unit 114 becomes conductive. This causes the charges held in the photoelectric conversion unit 111 to be transferred to the charge holding unit 112. The analog image signal has a voltage corresponding to the charges transferred and held by the charge holding unit 112. Further, the reference signal of the signal line VREF returns to the initial value. Thus, the waveform shaping circuit input becomes an H level.

At T13, the application of the ON signal to the signal line TRG stops, and the charge transfer unit 114 enters a non-conductive state. As a result, the exposure period ends.

At T14, the ramp-shaped voltage drop of the reference signal starts.

At T15, the reference signal becomes equal to the analog image signal. As a result, the waveform shaping circuit input transitions to an L level. This signal is shaped by the waveform shaping circuit 129 and input to the storage circuit 13. The storage circuit 13 further captures and stores the time code transferred by the transfer circuit for writing 20 at this time. This captured time code corresponds to the elapsed time from the start of the decrease of the reference signal at T14. The elapsed time corresponding to the voltage of the analog image signal based on incident light can be thus acquired.

At T16, the ramp-shaped voltage drop of the reference signal stops.

At T17, the reference signal returns to the initial state.

The arithmetic circuit 14 described in FIG. 2 subtracts the elapsed time corresponding to the voltage of the analog image signal at the time of resetting acquired at T10 from the elapsed time based on the voltage of the analog image signal acquired at T15. This causes the CDS described above to be executed. A digital signal corresponding to the elapsed time after the CDS corresponds to a digital image signal after analog-to-digital conversion. Analog-to-digital conversion of an image signal can be thus performed.

The drawing illustrates operation at high conversion efficiency in the pixel circuit 11. To have low conversion efficiency, a signal indicated by a dash-dot-dash line in the drawing is applied.

The drawing illustrates an example of a case where generation of an analog image signal in the pixel circuit 11 and comparison with the analog image signal and the reference signal in the comparison unit 12 are individually performed. The generation of the analog image signal in the pixel circuit 11 and the comparison between the analog image signal and the reference signal in the comparison unit 12 may be performed simultaneously in parallel. Specifically, after the charges of the photoelectric conversion unit 111 are transferred by the charge transfer unit 114 at T12 to T13, an ON signal may be applied to the signal line OFG to make the charge discharge unit 113 conductive to start exposure of the next frame.

The exposure and generation of an image signal in the pixel circuit 11 in the drawing and the analog-to-digital conversion of the image signal by the comparison unit 12 and the like are simultaneously performed in all the pixels 10 disposed in the pixel array unit 1. This configuration can perform global shutter for simultaneously performing exposure in all the pixels 10 and generate a digital image signal.

The configuration of the pixel circuit 11 is not limited to this example. For example, the capacitance switching unit 115 and the second charge holding unit 116 may be omitted. The charge discharge unit 113 may also be omitted. In this case, the discharge of the charges of the photoelectric conversion unit 111 is performed by electrically connecting the reset unit 117 and the charge transfer unit 114. Further, for example, a configuration in which a plurality of pixel circuits 11 are connected to one comparison unit 12 may also be adopted.

### [Other Configuration of Pixel Circuit and Comparison Unit]

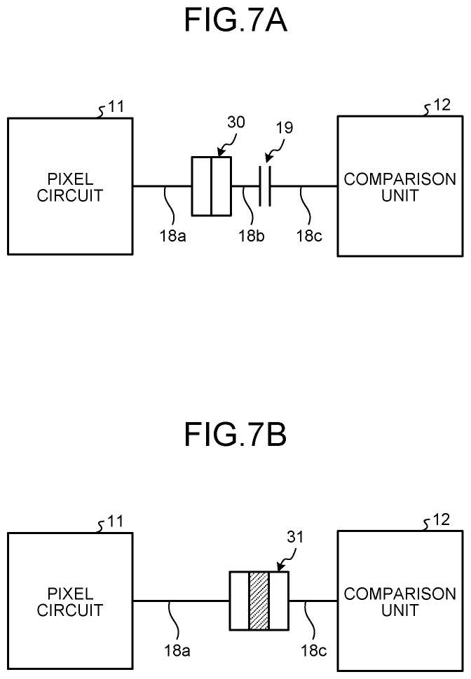

FIGS. 7A and 7B are diagrams each illustrating another configuration example of the pixel circuit and the comparison unit according to the first embodiment of the present disclosure. The drawings are circuit diagrams each illustrating another configuration example of the pixel circuit 11 and the comparison unit 12.

FIG. 7A is a diagram illustrating an example of a case where the coupling capacitor 19 is disposed on the second semiconductor chip 1002. Since the coupling capacitor 19 is disposed between the connection unit 30 and the comparison unit 12, the influence of the parasitic capacitance of the connection unit 30 to the comparison unit 12 can be reduced. The input of the comparison unit 12 is a voltage obtained by dividing the output voltage of the pixel circuit 11 by the parasitic capacitance of the connection unit 30 and the coupling capacitor 19. Assuming that the input voltage of the comparison unit 12 is Vin, Vin may be expressed as the following formula.

Vin=Vfd×C2/(C2+C1)

Here, Vfd represents an output voltage of the pixel circuit 11. C1 represents a parasitic capacitance on the image signal line 18c side. C2 represents the electrostatic capacitance of the coupling capacitor 19. In the configuration of FIG. 7A, C1 can be reduced. Therefore, a decrease in Vin can be reduced.

FIG. 7B is a diagram illustrating an example in which the coupling capacitor 19 is omitted and a connection unit 31 is disposed instead of the connection unit 30. The connection unit 31 is a connection unit in which a dielectric layer is disposed between the first pad 134 and the second pad 234. A configuration of the connection unit 31 will be described next.

### [Configuration of Connection Unit]

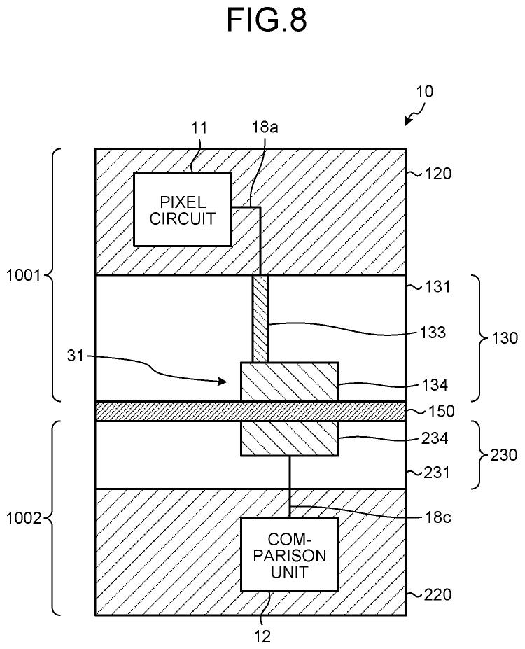

FIG. 8 is a view illustrating another configuration example of the connection unit according to the first embodiment of the present disclosure. The drawing is a sectional view illustrating a configuration example of the connection unit 31. Similarly to FIG. 5, the drawing is a sectional view illustrating a region of the connection unit 31 in the stacked first semiconductor chip 1001 and second semiconductor chip 1002.

The connection unit 31 in the drawing includes the first pad 134, the second pad 234, and a dielectric layer 150. The dielectric layer 150 is a dielectric disposed between the first pad 134 and the second pad 234. The dielectric layer 150 may be formed of an insulating film, for example, a SiO₂ film. Since the first pad 134 and the second pad 234 are disposed to face each other with the dielectric interposed therebetween, the connection unit 31 constitutes a capacitor. Thus, in the pixel 10 in the drawing, the coupling capacitor 19 can be omitted. Since the coupling capacitor 19 is omitted, the influence of the division of the output voltage of the pixel circuit 11 described above can be reduced. In addition, since the parasitic capacitance of the connection unit 31 added to the capacitance of the charge holding unit 112 described in FIG. 5 decreases, a decrease in conversion efficiency can also be reduced.

In this manner, in the imaging device 1000 according to the first embodiment of the present disclosure, the pixel circuit 11 and the comparison unit 12 are disposed on different semiconductor chips. The pixel circuit 11 and the comparison unit 12 are connected by the image signal line 18 in which the coupling capacitor 19 and the connection unit 30 are connected in series. This configuration can reduce the number of connection units disposed in the pixel 10 to one. The size of the pixel 10 can be reduced. Further, by disposing the coupling capacitor 19 in the image signal line 18, the pixel circuit 11 and the comparison unit 12 can be separated from each other in terms of direct current. This configuration can obtain the reset voltage of the pixel circuit 11 and the initial voltage at the time of initialization of the comparison unit 12 being different from each other. In the pixel circuit 11, the reset voltage can be increased to widen the dynamic range.

### 2. Second Embodiment

The imaging device 1000 according to the first embodiment described above uses the comparison unit 12 configured by a differential pair. The imaging device 1000 according to a second embodiment of the present disclosure is different from the above-described first embodiment in that the comparison unit 12 configured by a single-ended circuit is used.

### [Configuration of Pixel Circuit and Comparison Unit]

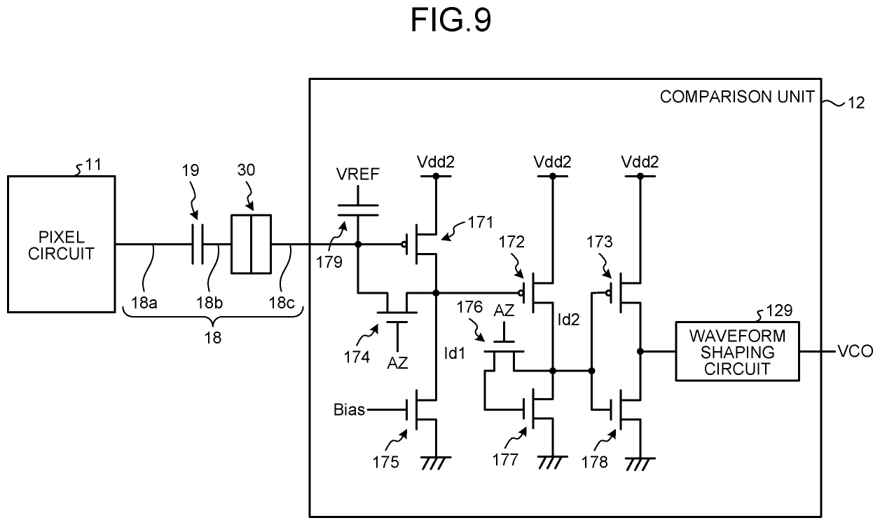

FIG. 9 is a diagram illustrating a configuration example of a pixel circuit and a comparison unit according to the second embodiment of the present disclosure. The drawing is a circuit diagram illustrating a configuration example of the pixel circuit 11 and the comparison unit 12 similarly to FIG. 4. The comparison unit 12 in the drawing is different from the comparison unit 12 in FIG. 4 in that it is configured by a single-ended circuit. The illustration of the pixel circuit 11 is simplified in the drawing.

The comparison unit 12 in the drawing includes MOS transistors 171 to 178, a capacitor 179, and the waveform shaping circuit 129. As the MOS transistors 171 to 173, p-channel MOS transistors may be used. As the MOS transistors 174 to 178, n-channel MOS transistors may be used.

The image signal line 18c is connected to the gate of the MOS transistor 171, the drain of the MOS transistor 174, and one end of the capacitor 179. The other end of the capacitor 179 is connected to the signal line VREF. The source of the MOS transistor 171 is connected to the power supply line Vdd2, and the drain is connected to the source of the MOS transistor 174, the drain of the MOS transistor 175, and the gate of the MOS transistor 172. The gate of the MOS transistor 175 is connected to the signal line Bias, and the source of the MOS transistor 175 is grounded. The source of the MOS transistor 172 is connected to the power supply line Vdd2, and the drain of the MOS transistor 172 is connected to the drain of the MOS transistor 176, the drain of the MOS transistor 177, the gate of the MOS transistor 173, and the gate of the MOS transistor 178.

The gate of the MOS transistor 176 is connected to the signal line AZ, and the source of the MOS transistor 176 is connected to the gate of the MOS transistor 177. The source of the MOS transistor 177 is grounded. The source of the MOS transistor 173 is connected to the power supply line Vdd2. The drain of the MOS transistor 173 and the drain of the MOS transistor 178 are commonly connected to the input of the waveform shaping circuit 129. The source of the MOS transistor 178 is grounded.

An analog image signal is input to the gate of the MOS transistor 171 via the coupling capacitor 19, and a reference signal is input thereto via the capacitor 179. The analog image signal and the reference signal are added and input to the gate of the MOS transistor 171. The MOS transistor 175 constitutes a constant current load of the MOS transistor 171. A current corresponding to the voltage supplied from the signal line Bias flows through the MOS transistor 175. Thus, a voltage corresponding to the voltage supplied by the signal line Bias and the voltage applied to the gate of the MOS transistor 171 is output.

Specifically, when the absolute value of the voltage Vgs between the gate and the source of the MOS transistor 171 is larger than the voltage supplied by the signal line Bias, the drain of the MOS transistor 123 becomes the H level. When the absolute value of the voltage Vgs between the gate and the source of the MOS transistor 171 is smaller than the voltage supplied by the signal line Bias, the drain of the MOS transistor 123 becomes the L level. Thus, when the reference signal is changed and the absolute value of the voltage Vgs between the gate and the source of the MOS transistor 171 exceeds the voltage supplied by the signal line Bias, the output of the MOS transistor 171 is inverted. As a result, the analog image signal and the reference signal can be compared. In this manner, the comparison unit 12 in the drawing detects and compares the difference between the signal obtained by adding the analog image signal and the reference signal and the voltage supplied by the signal line Bias.

The MOS transistor 172 and the MOS transistor 177 constitute an inverting amplifier circuit. The MOS transistor 177 constitutes a constant current load of the MOS transistor 172. Since the gate of the MOS transistor 172 is connected to the drain of the MOS transistor 171, a voltage obtained by inverting the input signal is output to the drain of the MOS transistor 172. At this time, it is preferable to adjust a drain current Id2 of the MOS transistor 172 to a value substantially equal to a drain current Id1 of the MOS transistor 171. This is because Id1 and Id2 flow exclusively in the comparison unit 12, and thus, the fluctuation of the power supply current flowing through the power supply line Vdd2 is reduced and the noise is reduced.

The MOS transistors 173 and 178 constitute an inverted buffer. As illustrated in the drawing, the MOS transistors 173 and 178 form an inverted buffer of a complementary metal oxide semiconductor (CMOS). By disposing the inverted buffer of the CMOS, it is possible to return the logic of the signal inverted by the circuit of the MOS transistors 177 and 178 to the original state while preventing an increase in the power supply current of the comparison unit 12. This is because a power supply current hardly flows in a CMOS circuit in a normal state. As a result, the power supply current of the comparison unit 12 can be limited to any one of Id1 and Id2 described above, and fluctuation of the power supply current can be prevented.

The MOS transistors 174 and 176 are transistors that initialize the comparison unit 12.

### [Generation of Image Signal]

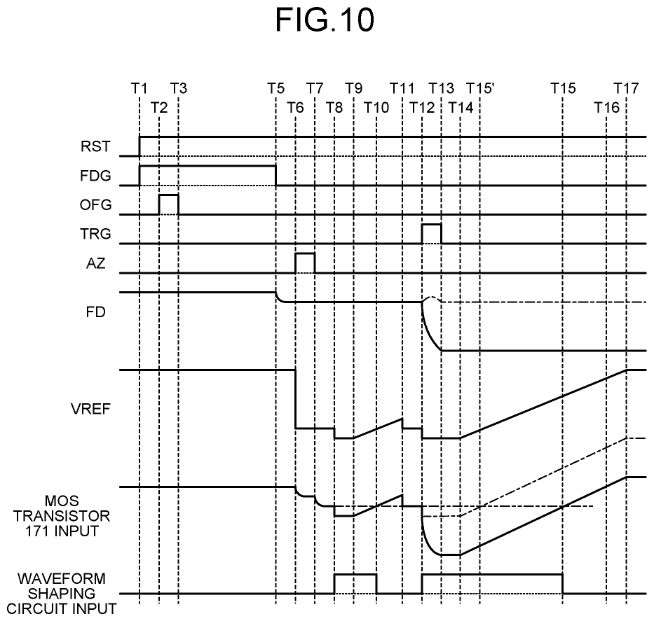

FIG. 10 is a diagram illustrating an example of generation of image signals according to the second embodiment of the present disclosure. Similarly to FIG. 6, the drawing is a timing chart illustrating processing in the pixel circuit 11 and the comparison unit 12. “MOS TRANSISTOR 171 INPUT” in the drawing represents a voltage input to the gate of the MOS transistor 171. The same symbols as in FIG. 6 are used otherwise.

In the initial state, the control signals of the signal line RST, the signal line FDG, the signal line OFG, the signal line TRG, and the signal line AZ have the value “0”. The analog image signal has a voltage at the time of resetting. The reference signal has a predetermined voltage.

At T1, an ON signal is applied from the signal line RST and the signal line FDG, the reset unit 117 and the capacitance switching unit 115 are conducted, and the charge holding unit 112 and the second charge holding unit 116 are reset.

At T2, an ON signal is applied from the signal line OFG, the charge discharge unit 113 is conducted, and the charges of the photoelectric conversion unit 111 are discharged.

At T3, the application of the ON signal from the signal line OFG stop, and the exposure period starts.

At T5, the application of the ON signal to the signal line FDG stops. As a result, the analog image signal has a voltage based on the charges or the like remaining in the charge holding unit 112.

At T6, an ON signal is applied from the signal line AZ, and the MOS transistors 174 and 176 are conducted. This causes the comparison unit 12 to be initialized. In addition, the reference signal changes to a low voltage. Unlike the reference signal of FIG. 6, the reference signal of the drawing is a signal in which the voltage increases in a ramp shape from a low initial voltage.

At T7, the application of the ON signal to the signal line AZ stops. The voltage of the reference signal at this time is an initialization voltage. The initialization voltage is applied to the gate of the MOS transistor 171.

At T8, a reference signal is applied from the signal line VREF. At this time, an initial value of the reference signal is applied. This initial value is a voltage lower than the above-described initialization voltage. The gate voltage (absolute value of Vgs) of the MOS transistor 171 becomes higher than the voltage of the signal line Bias, and the drain of the MOS transistor 171 is inverted to the H level. Thus, the input of the waveform shaping circuit 129 becomes an H level signal.

At T9, the ramp-shaped voltage rise of the reference signal starts.

At T10, the voltage obtained by adding the reference signal applied to the gate of the MOS transistor 171 and the analog image signal becomes equal to the voltage of the signal line Bias. As a result, the waveform shaping circuit input transitions to an L level. This signal is shaped by the waveform shaping circuit 129 and input to the storage circuit 13 described in FIG. 2.

At T11, the ramp-shaped voltage rise of the reference signal stops.

At T12, an ON signal is applied from the signal line TRG, the charge transfer unit 114 is conducted, and the charges held in the photoelectric conversion unit 111 are transferred to the charge holding unit 112. The analog image signal has a voltage corresponding to the charges transferred and held by the charge holding unit 112. Further, the reference signal of the signal line VREF returns to the initialization voltage. Thus, the waveform shaping circuit input becomes an H level.

At T13, the application of the ON signal to the signal line TRG stops, and the exposure period ends.

At T14, the ramp-shaped voltage rise of the reference signal starts.

At T15, the voltage obtained by adding the reference signal applied to the gate of the MOS transistor 171 and the analog image signal becomes equal to the voltage of the signal line Bias. The waveform shaping circuit input transitions to the L level. This signal is shaped by the waveform shaping circuit 129 and input to the storage circuit 13.

At T17, the ramp-shaped voltage rise of the reference signal stops, and the state returns to the initial state.

The arithmetic circuit 14 described in FIG. 2 executes CDS on the elapsed time based on the voltage of the analog image signal acquired at T10 and T15. Analog-to-digital conversion of the image signal can be thus performed.

This drawing assumes imaging of a subject with relatively high luminance. In the case of imaging a subject with low luminance, the analog image signal is a signal at a level indicated by the dash-dot-dash line of “FD” in the drawing. In this case, the voltage of the gate of the MOS transistor 171 is also a relatively high voltage as indicated by a dash-dot-dash line. At the timing of T15′ illustrated in the drawing, the waveform shaping circuit input transitions to the L level. In this manner, the pulse width of the input signal of the waveform shaping circuit 129 is narrowed at the time of imaging with low luminance. The digital image signal after analog-to-digital conversion also has a low value.

As illustrated in the drawing, in the comparison unit 12 of FIG. 9, the voltage of the initialization of the reference signal indicated by the two-dot chain line in the drawing is used as a reference, and the output of the comparison unit 12 is inverted when the voltage obtained by adding the reference signal and the analog image signal exceeds the level of the voltage of the initialization. Unlike the comparison unit 12 using the differential pair illustrated in FIG. 6, the voltage of the power supply line Vdd2 can be lowered. This configuration can achieve low power consumption.

Even in a case where the output of the comparison unit 12 is inverted, it is possible to reduce the fluctuation of the power supply current flowing through the power supply line Vdd2 as described with reference to FIG. 9, and thus, it is possible to reduce noise associated with the fluctuation of the power supply voltage.

In addition, since the coupling capacitor 19 is disposed in the image signal line 18 of the pixel circuit 11 and the comparison unit 12 and the reset of the pixel circuit 11 and the initialization of the comparison unit 12 are performed at different voltages, the reset voltage of the charge holding unit 112 of the pixel circuit 11 can be increased, and the dynamic range can be widened. Thus, the conversion efficiency can be increased, and the influence of noise can be relatively reduced.

In addition, since the comparison unit 12 is configured by a single-ended circuit, the number of active devices in the initial stage of the comparison unit 12 can be halved as compared with a case where a differential pair is used. Since the number of MOS transistors that become noise sources is reduced, noise can be reduced as compared with the comparison unit 12 in FIG. 4.

Further, at the time of initialization of the comparison unit 12, since the variation in the threshold voltage of the MOS transistor 171 for each pixel 10 is canceled, variation in the timing of inversion of the output of the comparison unit 12 is reduced. As a result, the comparison unit 12 can be set to a high gain, and noise can be relatively reduced.

The configuration of the imaging device 1000 other than this is the same as the configuration of the imaging device 1000 in the first embodiment of the present disclosure, and thus description thereof is omitted.

In this manner, the imaging device 1000 according to the second embodiment of the present disclosure can perform analog-to-digital conversion of an analog image signal using the comparison unit 12 configured by a single-ended circuit.

The effects described in the present specification are merely examples and are not restrictive of the disclosure herein, and other effects may be achieved.

The present technology may also take the following configurations.

(1)

An imaging sensor comprising:
a first semiconductor chip including a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit;
a second semiconductor chip stacked on the first semiconductor chip, the second semiconductor chip including a comparison unit that compares the analog image signal with a reference signal whose voltage changes at a predetermined ratio as time elapses, and a conversion unit that converts the analog image signal into a digital image signal based on a result of the comparison; and
an image signal line that transmits an analog image signal output from the pixel circuit to the comparison unit via a connection unit and a coupling capacitor disposed between the first semiconductor chip and the second semiconductor chip,
wherein at least one of the comparison unit and the conversion unit is disposed at a position overlapping the pixel circuit in plan view.
   (2)

The imaging sensor according to the above (1), wherein
the connection unit includes a first pad disposed on the first semiconductor chip and a second pad disposed on the second semiconductor chip.
   (3)

The imaging sensor according to the above (2), wherein
the connection unit is formed by joining the first pad and the second pad.
   (4)

The imaging sensor according to the above (3), wherein
in the connection unit, the first pad and the second pad are joined via an insulating film.
   (5)

The imaging sensor according to the above (4), wherein
the coupling capacitor is configured by the connection unit.
   (6)

The imaging sensor according to any one of the above (1) to (4), wherein
the coupling capacitor is disposed on the first semiconductor chip.
   (7)

The imaging sensor according to any one of the above (1) to (4), wherein
the coupling capacitor is disposed on the second semiconductor chip.
   (8)

The imaging sensor according to any one of the above (1) to (7), wherein
the comparison unit performs the comparison by detecting a difference between the analog image signal and the reference signal.
   (9)

The imaging sensor according to any one of the above (1) to (8), wherein
the comparison unit performs the comparison by detecting a difference between a signal to which the analog image signal and the reference signal input via a second coupling capacitor are added and a predetermined reference voltage.
   (10)

The imaging sensor according to the above (9), wherein
the comparison unit is configured by an amplifier circuit including a transistor to which a constant current load that causes a current according to the reference voltage to flow is connected and to which the signal to which the analog image signal and the reference signal are added is input.
   (11)

The imaging sensor according to the above (10), wherein
the comparison unit further includes an inverting amplifier circuit configured by a transistor connected to a constant current load that is connected to an output of the amplifier circuit and that causes substantially the same current as the constant current load to flow.
   (12)

The imaging sensor according to any one of the above (1) to (11), wherein
the pixel circuit is supplied with power different from power of the comparison unit.
   (13)

The imaging sensor according to any one of the above (1) to (12), wherein
the first semiconductor chip includes a plurality of the pixel circuits,
the second semiconductor chip includes a plurality of the comparison units and a plurality of the conversion units each being disposed in each of the plurality of pixel circuits, and
the imaging sensor further comprises a plurality of the image signal lines that transmit the analog image signal output from the plurality of pixel circuits to each of the plurality of comparison units.
   (14)

An imaging device comprising:
a first semiconductor chip including a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit;
a second semiconductor chip stacked on the first semiconductor chip, the second semiconductor chip including a comparison unit that compares the analog image signal with a reference signal whose voltage changes at a predetermined ratio as time elapses, and a conversion unit that converts the analog image signal into a digital image signal based on a result of the comparison;
an image signal line that transmits an analog image signal output from the pixel circuit to the comparison unit via a connection unit and a coupling capacitor disposed between the first semiconductor chip and the second semiconductor chip; and
a processing circuit that processes the image signal,
wherein at least one of the comparison unit and the conversion unit is disposed at a position overlapping the pixel circuit in plan view.

### REFERENCE SIGNS LIST

1 PIXEL ARRAY UNIT
3 HORIZONTAL SCANNING CIRCUIT
8 IMAGE PROCESSING UNIT
10 PIXEL
11 PIXEL CIRCUIT
12 COMPARISON UNIT
18 IMAGE SIGNAL LINE
19 COUPLING CAPACITOR
30, 31 CONNECTION UNIT
111 PHOTOELECTRIC CONVERSION UNIT
112 CHARGE HOLDING UNIT
114 CHARGE TRANSFER UNIT
117 RESET UNIT
121 to 127, 171 to 178 MOS TRANSISTOR
128, 179 CAPACITOR
129 WAVEFORM SHAPING CIRCUIT
134 FIRST PAD
234 SECOND PAD
1000 IMAGING DEVICE
1001 FIRST SEMICONDUCTOR CHIP
1002 SECOND SEMICONDUCTOR CHIP
1010 PIXEL REGION

1. An imaging sensor comprising:
a first semiconductor chip including a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit;
a second semiconductor chip stacked on the first semiconductor chip, the second semiconductor chip including a comparison unit that compares the analog image signal with a reference signal whose voltage changes at a predetermined ratio as time elapses, and a conversion unit that converts the analog image signal into a digital image signal based on a result of the comparison; and
an image signal line that transmits an analog image signal output from the pixel circuit to the comparison unit via a connection unit and a coupling capacitor disposed between the first semiconductor chip and the second semiconductor chip,
wherein at least one of the comparison unit and the conversion unit is disposed at a position overlapping the pixel circuit in plan view.

2. The imaging sensor according to claim 1, wherein
the connection unit includes a first pad disposed on the first semiconductor chip and a second pad disposed on the second semiconductor chip.

3. The imaging sensor according to claim 2, wherein
the connection unit is formed by joining the first pad and the second pad.

4. The imaging sensor according to claim 3, wherein
in the connection unit, the first pad and the second pad are joined via an insulating film.

5. The imaging sensor according to claim 4, wherein
the coupling capacitor is configured by the connection unit.

6. The imaging sensor according to claim 1, wherein
the coupling capacitor is disposed on the first semiconductor chip.

7. The imaging sensor according to claim 1, wherein
the coupling capacitor is disposed on the second semiconductor chip.

8. The imaging sensor according to claim 1, wherein
the comparison unit performs the comparison by detecting a difference between the analog image signal and the reference signal.

9. The imaging sensor according to claim 1, wherein
the comparison unit performs the comparison by detecting a difference between a signal to which the analog image signal and the reference signal input via a second coupling capacitor are added and a predetermined reference voltage.

10. The imaging sensor according to claim 9, wherein
the comparison unit is configured by an amplifier circuit including a transistor to which a constant current load that causes a current according to the reference voltage to flow is connected and to which the signal to which the analog image signal and the reference signal are added is input.

11. The imaging sensor according to claim 10, wherein
the comparison unit further includes an inverting amplifier circuit configured by a transistor connected to a constant current load that is connected to an output of the amplifier circuit and that causes substantially the same current as the constant current load to flow.

12. The imaging sensor according to claim 1, wherein
the pixel circuit is supplied with power different from power of the comparison unit.

13. The imaging sensor according to claim 1, wherein
the first semiconductor chip includes a plurality of the pixel circuits,
the second semiconductor chip includes a plurality of the comparison units and a plurality of the conversion units each being disposed in each of the plurality of pixel circuits, and
the imaging sensor further comprises a plurality of the image signal lines that transmit the analog image signal output from the plurality of pixel circuits to each of the plurality of comparison units.

14. An imaging device comprising:
a first semiconductor chip including a pixel circuit that includes a photoelectric conversion unit that performs photoelectric conversion of incident light, a charge holding unit that holds a charge generated by the photoelectric conversion, and a reset unit that resets the charge holding unit, the pixel circuit outputting an analog image signal corresponding to the charge held in the charge holding unit;
a second semiconductor chip stacked on the first semiconductor chip, the second semiconductor chip including a comparison unit that compares the analog image signal with a reference signal whose voltage changes at a predetermined ratio as time elapses, and a conversion unit that converts the analog image signal into a digital image signal based on a result of the comparison;
an image signal line that transmits an analog image signal output from the pixel circuit to the comparison unit via a connection unit and a coupling capacitor disposed between the first semiconductor chip and the second semiconductor chip; and
a processing circuit that processes the image signal,
wherein at least one of the comparison unit and the conversion unit is disposed at a position overlapping the pixel circuit in plan view.
